(19) United States
(12) Patent Application Publication
(10) Pub. No.: US 2024/0176064 A1
(43) Pub. Date: May 30, 2024

(54) POLYMER-COMPOSITE MATERIAL WITH LIGHT CONCENTRATING AND SPECTRAL SHIFTING PROPERTIES

(71) Applicant: Ian D. HOSEIN, Minoa, NY (US)

(72) Inventor: Ian D. HOSEIN, Minoa, NY (US)

(73) Assignee: SYRACUSE UNIVERSITY, Syracuse, NY (US)

(21) Appl. No.: 18/523,375

(22) Filed: Nov. 29, 2023

Related U.S. Application Data
(60) Provisional application No. 63/428,599, filed on Nov. 29, 2022.

(51) Int. Cl. G02B 6/02; G02B 1/02; G02B 1/04; G02B 6/10; H01L 31/048

(52) U.S. Cl. CPC G02B 6/0229; G02B 1/02; G02B 1/046; G02B 6/102; H01L 31/0481

(57) ABSTRACT

A polymer composite for use as a solar cell encapsulant is defined by a thin film having a first side and an opposing second side and at least one optical structure formed in the film. The least one optical structure includes one or more waveguide formed by a core of a high-refractive index polymer, such as an acrylate and a cladding of a low refractive index polymer, such as a silicone. In a preferred embodiment, two intersecting waveguide arrays are defined, each having waveguides disposed at equal and opposite angles in relation to a normal of a surface of the film. The polymer composite further includes at least one light conversion material that is capable of upconverting and/or downconverting UV and/or IR portions of light entering the film into visible light.

### CROSS REFERENCE TO RELATED APPLICATION

This application claims priority under relevant portions of 35 USC §119 and 35 USC §120 to U.S. Patent Application Ser. No. 63/428,599, filed Nov. 29, 2022, entitled: POLYMER-COMPOSITE MATERIAL WITH LIGHT CONCENTRATING AND SPECTRAL SHIFTING PROPERTIES, the entire contents of which are herein incorporated by reference.

### STATEMENT REGARDING FEDERALLY SPONSORED RESEARCH AND DEVELOPMENT

This invention was made with government support under Grant No. 1903592, awarded by the National Science Foundation (NSF). The government has certain rights in the invention.

### BACKGROUND OF THE INVENTION

### Field of the Invention

The present invention relates to solar cell light concentrators and, more specifically, to a polymer composite film for encapsulating solar cells that captures a wider incident angular range and wider spectral range of light to increase the total energy flux to a solar cell to which the polymer composite film is attached.

### DESCRIPTION OF THE RELATED ART

Solar energy is becoming increasingly important as a source of clean and renewable energy. According to the International Energy Agency, global solar photovoltaic (PV) capacity has grown from 8 GW to over 770 GW in 2020, representing a significant increase in solar energy adoption worldwide. Solar energy has the potential to reduce greenhouse gas emissions and provide access to electricity in remote and off-grid areas. Therefore, developing more efficient and cost-effective solar energy technologies is crucial in meeting the world's growing energy demand while reducing dependence on fossil fuels. Solar cells are important energy conversion technologies that play a critical role in expanding green energy production in the power grid. In addition to land-based applications, solar cells are also critical for space technologies such as spacecraft and satellites. Solar cells must be able to operate in extreme environments, collecting as much solar radiation as possible to maximize power delivery. Hence, development of more efficient and reliable solar cells can greatly improve the performance and longevity of space technologies, enabling a wide range of applications from communications and navigation to weather monitoring and scientific research. Thus, solar cell research and development is important not only for Earth-based energy solutions, but also for advancements in space technology.

In order to maximize electrical output, it is necessary to increase the total solar energy flux that is converted by solar cells. A critical issue that persists with photovoltaic technology, in particular, is the significant mismatch between their spectral response and the solar radiation spectrum, which limits their ability to collect light over a wider range of wavelengths. Many solar cell technologies, however, possess a spectral response range that is narrower, misaligned and/or mismatched with the solar spectrum that is incident on the cells. In this regard, silicon (Si) solar cells, the dominant type of solar cell for energy conversion, have a narrow spectral response window (˜400 to ˜900 nm) with sharp drop-offs in the infrared (IR) and ultraviolet (UV) regions, leaving a significant portion of the solar spectrum unharvested. A large percentage of the total solar spectrum irradiated on the Earth's surface is in the infrared (IR) region of the electromagnetic spectrum, which, as noted, is well above the spectral response range of many solar cells. Additionally, a significant portion of the sun's energy is in the form of UV radiation, with UV-A radiation (315-400 nm) being the most abundant in the solar spectrum. High energy ultraviolet (UV) light is also not efficiently converted by solar cells.

Present solutions in broadening the spectral response range of solar cells entails changing or tuning the composition of the solar cell layers to better match or align the effective range of the solar cells with specific portions of the electromagnetic spectrum of solar flux. Some approaches involve the tandem use of multiple cells with different spectral response ranges in order to cover a wider spectral range. Other known solutions entail tuning or applying different types of structures or compositions onto the surface of the solar cell. The drawback to these approaches is that they require changes to the composition or architecture of the solar cell, which are not only expensive but which actually can lead to an overall reduction in performance. Accordingly, there is a prevailing need in the field for an approach that can widen the spectral response range of solar cells, but without requiring significant changes in their design or architecture.

### BRIEF DESCRIPTION OF THE INVENTION

To tend to the above-noted needs in the field, the present invention provides a novel approach to improving the spectral range of a solar cell by using a polymer composite encapsulate with an enhanced energy capturing design, in lieu of conventional plastic encapsulants that are currently used in order to protect solar cells from the elements. The polymer composite encapsulate of the present invention includes suitable optical structures and light-responsive compositions to provide greater collection and conversion of solar radiation across a wider spectrum of incident solar energy. The use of suitable optical structures in the resin of the polymer encapsulate can enable more light from a wide angular incident range to be collected, thereby increasing the total solar energy flux converted over the course of a day and across seasons, as the sun moves across the sky in accordance with its diurnal trajectory.

Therefore and according to at least one aspect of the present invention, there is provided an encapsulant for a solar cell, comprising: a film having a first side and an opposing second side; at least one optical structure formed in the film, the at least one optical structure comprising at least a first waveguide array positioned between the first and second sides, wherein each waveguide in the at least one first waveguide array is commonly oriented at a first angle relative to a normal of a surface of the film and in which each waveguide of the first waveguide array is formed by a core of a high-refractive index acrylate monomer and a cladding of a low refractive index epoxide monomer; and at least one light conversion material comprising a fluorescent dye-tagged acrylate monomer disposed in the core of each waveguide.

According to another aspect of the present invention, there is provided an encapsulant for a solar cell, the encapsulant comprising: a film having a first side and an opposing second side; a first waveguide array formed in the film and positioned between the first and second sides, wherein each waveguide in the first waveguide array is commonly oriented at a first angle relative to a normal of a surface of the film; a second waveguide array formed in the film and positioned between the first and second sides, wherein each waveguide in the second waveguide array is commonly oriented at a second angle relative to a normal of a surface of the film, wherein each waveguide of the first waveguide array and each waveguide of the second waveguide array is formed by a core of a high-refractive index acrylate monomer and a cladding of a low refractive index epoxide monomer, wherein the first angle and second angle are opposite to one another relative to a normal of the surface of the film; and in which the encapsulant further comprises a fluorescent dye-tagged acrylate included in the formed core of each waveguide of the first and second array of waveguides.

According to yet another aspect of the present invention, there is provided an encapsulant for a solar cell, comprising: a film having a first side and an opposing second side; a first waveguide array formed in the film and positioned between the first and second sides, wherein each waveguide in the first waveguide array is commonly oriented at a first angle relative to a normal of a surface of the film; a second waveguide array formed in the film and positioned between the first and second sides, wherein each waveguide in the second waveguide array is commonly oriented at a second angle relative to a normal of a surface of the film, wherein each waveguide of the first waveguide array and each waveguide of the second waveguide array is formed by a core of a high-refractive index acrylate monomer and a cladding of a low refractive index epoxide monomer, wherein the first angle and second angle are opposite to one another relative to a normal of the surface of the film; and wherein the encapsulant further comprises a light converting material comprising a quantity of nanoparticles disposed in the first and second waveguide arrays, the nanoparticles being capable of upconverting IR portions of light entering the first side into visible light.

An advantage realized by the herein described invention is that the ability to transmit ultrawide angles of light via more direct paths mitigates effects that cause losses, such as shading from the solar cell's front contacts, thereby leading to efficiency enhancements.

Another advantage is that the wide-angle light conversion achieved by the waveguide arrays of the herein described polymer film encapsulate would allow for greater flexibility in solar installation locations and extend time of sustained energy generation, that is, earlier in the morning and later in the evening, as well as in winter seasons at which time the sun is closer to the horizon. Accordingly, the photovoltaic (PV) modules of the solar cell are more omnidirectional regarding their position, being orientation agnostic, and therefore more versatile in the powering of infrastructure, homes, buildings, and typically nonoptimal geographic locales.

Moreover, a combination of wide-angle optical structures, and light conversion formulations provided in the herein described polymer film encapsulate enables tenability and versatility in terms of angular receipt of incident light as well as increasing the overall current density and power transmission capabilities of solar cells.

These and other features and advantages will be readily apparent from the following Detailed Description, which should be read in conjunction with the following drawings.

### BRIEF DESCRIPTION OF THE DRAWINGS

The accompanying drawings, which are incorporated herein and constitute part of this specification, illustrate presently preferred embodiments of the invention, and together with the general description given above and the detailed description given below, serve to explain features of the invention (in which like numerals represent like elements), of which:

FIG. 1 presents optical microscopy (top and cross sectional) images of various optical structures made in accordance with aspects of the present invention including a single waveguide (WG) lattice with a 0° orientation angle, and a double waveguide (2WG) lattice having intersecting 25° angles, each of the WG and 2WG waveguide lattices further having different dye concentrations of 0, 0.1 wt % and 0.5 wt %, respectively;

FIG. 2 represents comparative images of the fluorescence emission of waveguide and non-waveguide structures having various dye concentrations under ultraviolet irradiation from samples of polymer composite film that have been made in accordance with aspects of the present invention and as further compared to control samples without waveguide (optical) structures;

FIGS. 3(a)-3(c) depicts fluorescence emission spectra of various photopolymer blends of dye as incorporated in various optical structures disposed in polymer composite film samples which are made in accordance with aspects of the present invention;

FIG. 4(a) presents transverse intensity profiles of transmitted incandescent light through various optical structures and more specifically single vertically aligned waveguide (WG) lattice structures over a range of incident angles (0°-70°) and dye concentrations (0 wt %, 0.1 wt %, 0.5 wt %, respectively), in accordance with aspects of the present invention;

FIG. 4(b) presents transverse intensity profiles of transmitted incident light through double waveguide (2WG) lattice structures over a range of incident angles (0°-70°) and dye concentrations (0 wt %, 0.1 wt %, 0.5 wt %, respectively), in accordance with aspects of the present invention;

FIG. 5 presents transverse intensity profiles of transmitted incandescent light through uniformly cured waveguide structures over a range of incident angles (0°-70°) and dye concentrations (0 wt %, 0.1 wt %, 0.5 wt %, respectively), in accordance with aspects of the present invention;

FIGS. 6(a)-6(c) depict graphical views of solar cell performance of silicon solar cells that have been encapsulated with various dye-incorporated polymer films (0 wt %, 0.1 wt %, 0.5 wt %) and optical structures (uniform, WG, 2WG lattices) in accordance with aspects of the present invention, and more specifically short current density comparisons between same;

FIGS. 6(d)-6(f) depict graphical views of nominal changes in short current density for the uniform, WG and 2WG optical structures of FIGS. 6(a)-6(c), respectively, each comparatively showing the effects of dye incorporation (0.1 wt % and 0.5 wt %) thereon and over a range of incident angles (0°-70°);

FIGS. 6(g)-6(h) depict graphical views of nominal changes in short current density based on different dye incorporations (0.1 wt % and 0.5 wt %), respectively, each comparatively showing the effects of optical structure (control/uniform, WG and 2WG lattices) thereon and over a range of incident angles (0°-70°);

FIG. 6(i) is a contour plot depicting nominal change in short current density over each of the optical structures and dye concentrations of FIGS. 6(a)-6(h);

FIGS. 6(j)-6(l) depict graphical results of power conversion efficiencies for solar cells encapsulated with various polymer films made in accordance with aspects of the present invention, and more specifically those having uniform optical structures per FIG. 6(j)), WG optical structures per FIGS. 6(k), and 2WG optical structures, FIG. 6(l), for dye concentrations of 0 wt %, 0.1 wt % and 0.5 wt %, respectively;

FIG. 7 schematically depicts the advantageous effects of the combination of a polymer composite film having a fluorescent dye-tagged monomer emission for purposes of ultraviolet (UV) down conversion with optical structures in the form of waveguide lattices for purposes of wide angle collection of incident light in accordance with aspects upon a solar cell encapsulated with the polymer film;

FIG. 8 is a schematic of a waveguide array structure for a polymer film encapsulate in accordance with various aspects of the present invention;

FIGS. 9(a) and 9(b) depict optical microscopy images of the cross-section and top surface, respectively, of a polymer film encapsulate of FIG. 8;

FIGS. 9(c) and 9(d) are images of a simulated emission of dye and imbedded nanoparticles for concentrations of 0.1 and 0.5 wt %, respectively, for samples employing the polymer film encapsulate of FIG. 8;

FIGS. 10(a)-10(b) depict a series of J-V curves for an exemplary solar cell that has been encapsulated with a polymer composite film having various optical structures (waveguide lattices), with two different dye weight fractions in accordance with aspects of the present invention;

FIG. 10(c) is a plot of the short circuit (V=0) current density as a function of light incident angle, with respect to a uniform polymer composite film having no dye content;

FIG. 11 is a graph depicting various J-V curves for solar cells (polycrystalline Si) encapsulated with structure at 0.1 wt % nanoparticles, demonstrating the enhancement in current density at short circuit (V=0) of the material with the up-conversion nanoparticles, as compared to a similar material with no nanoparticles, or even the bare solar cell;

FIG. 12 is a graph summarizing angle-resolved solar tester requirements (AM 1.5 G) for polymer encapsulated solar cells having a dye concentration of (0.1 wt %)+optical waveguide (WG) structures in accordance with aspects of the present invention; and

FIG. 13 is a graph of angle-resolved short circuit current density for solar cells, contrasting those encapsulated with a polymer composite film devoid of no up-conversion nanoparticles and a polymer composite film having a quantity of up-conversion nanoparticles (0.1 wt %) in which the solar cell is irradiated with broadband light>975 nm, to examine light conversion in the IR region.

### DETAILED DESCRIPTION

The following relates to exemplary embodiments of a polymer composite film encapsulate for use on solar cell concentrators. Generically, each polymer composite as described herein is generally provided with one or more optical structures such as one or more waveguide arrays, each having waveguide cores made from a high refractive index polymer and cladding made from a low refractive index polymer, in which each of these polymers are capable of being photo-cured. The polymer composite can further include one or more light conversion materials or formulations used in combination with the one or more optical structures. It will be readily understood that there are a number of modifications or variations that will become apparent to one of sufficient skill reading this Detailed Description. In addition, the accompanying drawings are intended to show salient features of the present invention. The drawings should not be used for scalar purposes. As used herein, the terms “about” or “approximately” for any numerical values or ranges indicate a suitable dimensional tolerance that allows the part or collection of components to function for the intended purpose as described herein. More specifically, “about” or “approximately” may refer to the range of values±10 percent of the recited value, e.g., “about 90%” may refer to the range of values from 81% to 99%.

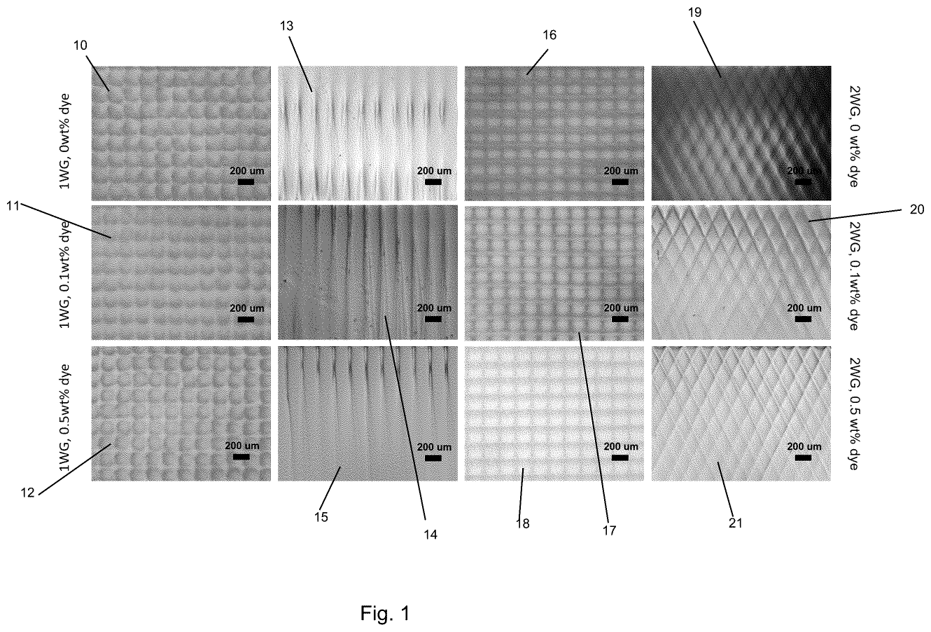

With reference to FIGS. 1-7 and according to a first embodiment, samples of a polymer composite film 10 were prepared, the samples having various optical structures and light-conversion formulations. More specifically, the polymer composite film samples according to this embodiment are defined by one or more waveguide arrays, as well as a fluorescent dye for purposes of light conversion wherein the composite film is chiefly made from three (3) components, namely a high refractive index acrylate monomer, a low refractive index epoxide monomer, and a dye-tagged monomer. As noted, the polymer composite can include optical structures (waveguide arrays) in which the cores and cladding can be made from any photo-curable polymer with high and low refractive indices, respectively. However, acrylates are generally good for forming waveguide cores and silicones are generally good for forming cladding, as discussed in greater detail below.

According to this specific embodiment, the high refractive index acrylate monomer used is Norland Optical Adhesive 65 (NOA 65), purchased from Norland Products Inc. The low refractive index epoxide monomer used according to this embodiment is an epoxide terminated PDMS (polydimethylsiloxane) oligomer, obtained from Sigma-Aldrich. The dye-tagged monomer used herein is fluorescein o,o′-dimethacrylate, which is also purchased from Sigma Aldrich. In addition, a free-radical photo-initiator camphorquinone (CQ), from Sigma Aldrich, and cationic initiator (4-octyloxyphenyl) phenyliodium hexafluoroantimonate (OPPI) from Hampford Research, Inc., were employed. All chemicals were used as received.

According to this embodiment, two (2) different formulations of photopolymerizable media were prepared; namely, a control sample manufactures from pure NOA65, and a binary blend of NOA65 and PDMS. For each formulation, the relative weight fractions of 2.5 and 1.5 wt % were employed for the photoinitiator CQ and cationic initiator OPPI, respectively (as a percentage of total mass weight). The selected binary photoreactive blend had a composition of 20/80 (wt %/wt %) of PDMS/NOA65 for all prepared formulations. The dye concentrations employed for each of the prepared formulations were 0 wt %, 0.1 wt %, and 0.5 wt %, respectively. Samples prepared from precursors containing 0 wt % dye served as a control for the purpose of making comparisons, as discussed infra. According to this embodiment, a mask pattern made up of 40 μm apertures arranged in a square array of 200 μm interspacing was used to produce all waveguide lattices. Light was provided by one or more Light-Emitting Diodes (LEDs), each emitting blue light at a peak wavelength of 470 nm, corresponding to the maximum absorption peak of the free-radical initiator of CQ.

For purposes of fabricating a composite polymer film, the photoreactive precursors were measured, added to a vial, and wrapped with aluminum foil. The mixture was then mixed with the assistance of a magnetic stir bar and kept under dark conditions for 24 hours to form a homogeneously mixed resin prior to use. The blend was injected into a Teflon ring (1.8 cm in diameter) mounted over a thin glass substrate to a height of 3 mm and placed over the center of the optical mask, which was overlaid at the center of the confocal region of the one or more LED light sources. The irradiated LED light passes through the mask to generate a vertical array or two arrays of ±25° slant-oriented microscale optical beams (relative to the surface normal), which propagation through the blends to induce the formation of the waveguide lattices, as done previously wherein the acrylate monomer forms a cylindrical core and the epoxide monomer forms the surrounding cladding of each waveguide. As control samples, the uniformly cured NOA65 films were prepared under irradiation with a single, normally incident LED beam, and without the use of a photomask.

In terms of equipment, refractive index values for the photocured formulations and homogeneous binary blends were measured using an Abbe refractometer (Atago, NAR-IT SOLID), while fluorescence emission spectra were acquired by exciting the fluorophore molecule at the maximum absorption peak of 480 nm. The wavelengths of fluorescence emission collection were selected in the range of 495 and 650 nm for all samples. A hand-held UV dark lamp was used to visually observe the fluorescence of the samples prepared herein according to this specific embodiment and as discussed infra.

A Zeiss Axioscope equipped with an Axiocam 105 color camera, operated by Zeiss imaging software, was used to capture optical images of the various waveguide lattices. The transverse spatial intensity profile of incandescent light from a QTH source transmitted through photocured samples was captured with a charge-coupled device (CCD) camera (Dataray Inc.), using a suitable optics setup.

A planar multi-crystalline silicon (Si) screen-printed solar cell (15 cm×5 cm×0.5 mm), with a measured short circuit density of 35.5 mA/cm², was used in this specific embodiment. Each of the prepared and photocured samples were laminated onto the solar cell (15 cm, 5 cm, 0.5 mm), which was first primed with a 0.12 mm layer of PDMS (Sylgard). Current density-voltage (J-V) curves of the encapsulated solar cell were collected under solar simulated irradiation (AM 1.5 G).

FIG. 1 presents a series of optical microscopy images of various waveguide structures and dye concentrations of the uniform and photo-cured film samples made in accordance with this embodiment. More specifically, images 10, 11 and 12 illustrate top face images (namely the side from which light enters the film), and images 13, 14, and 15 illustrate cross sectional views taken of a single waveguide lattice structure (hereinafter referred to as “WG”) having an array of waveguides oriented normal to a surface of the film and having different dye concentrations (0, 0.1, 0.5 wt %) of the precursor mixtures. Similarly, images 16, 17, 18 represent top face view and images 19, 20, 21 represent cross section views of a double waveguide lattice structure (herein referred to as “2WG”), having intersecting waveguide arrays oriented at ±25° relative to normal to a surface of the prepared polymer composite films, and having three (3) different dye concentrations (0, 0.1, and 0.5 wt %) of the precursor mixtures. The scale bar for each image as shown and labeled is 200 μm. The surfaces and cross sections of the WG lattice structures and 2WG lattice structures reveal the periodicity and uniformity of the waveguides in their respective lattices, and specifically the two intersecting lattices of the 2WG structure. Large scale uniformity in the formed film structure is crucial for their optical properties, particularly for large scale deployment of the prepared coatings over solar cells.

For purposes of this embodiment, the dye-tagged monomer was incorporated into the cores of the waveguides for each of the WG and 2WG lattice structures, leading to better transmission of light along the intended direction of the waveguides, and ultimately improving performance in certain applications. In this regard and with reference to the cross-sectional images of FIG. 1, the waveguide cores produced with dye-incorporated formulations, see images 14, 15, 20, 21 are comparatively clearer and more distinct along their lengths across the film thickness, as indicated by their continuous lateral fiber shape along their length. The inclusion of dye in the photo-reactive formulations resulted in waveguide cores with more distinct and clear cross-sections. It was determined in this embodiment that a dye concentration of 0.1 wt % was optimal for producing the clearest waveguide cores in the case of the single WG lattice (1WG), while for the 2WG structure, a continuous improvement in the quality of the structure was observed with increasing dye concentration, with 0.5 wt % yielding the clearest structure throughout the depth of the polymer film.

Still referring to FIG. 1, the benefits of the dye in providing improved contrast are particularly noticeable in the 2WG structures, see images 17, 18, 20, 21 as there is observed an improved structure with an increased weight fraction of dye. Although the waveguide core diameters in all structures do become divergent and increase in diameter over their length, their consistent diameters at the top of the film for more than ˜1 mm is sufficient to establish the transmission of collected light along the intended direction of the waveguides. It is quite beneficial that the incorporation of a dye-tagged monomer in the formulation, which copolymerizes with the high-index polymer, contributes to the quality of the structure. The dye may absorb light within the spectral region of the blue LED employed in the synthesis, which could help to absorb light that may stray or scatter into the dark regions, thereby providing better contrast between irradiation and non-irradiation regions.

In summary, the optical microscopy images presented in FIG. 1 demonstrate that both single and double (WG and 2WG) structures can be successfully produced from formulations with a dye-tagged monomer, resulting in structures that appear visually of higher quality. These results have implications for the performance of the structures particularly in the field of solar cells, where large scale uniformity in the structure is crucial for their optical properties, as further discussed herein.

Incorporating a fluorescent function of a fluorescein dye via its acrylate-tagged monomer (in this example, fluorescein o,o′-dimethacrylate) is an attractive option due to fluorescein's very high molar absorptivity (at ˜488 nm), large fluorescence quantum yield (98%), and high photostability, making this dye an ideal candidate to improve the effective spectrum of light collection for solar cells. Fluorescein dye was also chosen for its strategic position of its excitation spectrum. To qualitatively examine the emission characteristics of dye in the polymerized thin films and the effect of dye concentration on observable emission, images of their fluorescence was first collected to understand the dye emission in the prepared thin films.

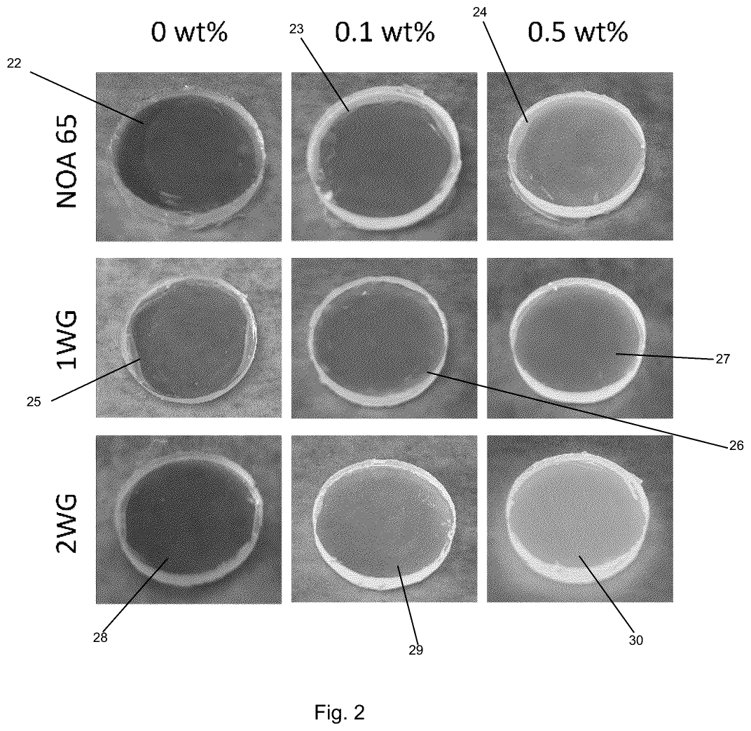

More specifically, FIG. 2 shows the images of fluorescence emission from uniform, 1WG, and 2WG structures with 0, 0.1, and 0.5 wt % dye concentrations, respectively, and under UV irradiation. Firstly, all dye-containing samples, see images 24, 27, 29, 30 emitted a uniform, bright, yellow-green color as compared samples having no dye concentration, see images 22, 25, 28. Remarkably, the brightness of the sample fluorescence also visually appears to increase from uniform, to a single WG, to 2WG, namely, with more waveguide lattices disposed in the polymer film. These visual observations provide qualitative confirmation of the fluorescence intensities determined from the emission spectra (as discussed infra). Samples with 0 wt %, see images 22, 25, 27 were irradiated with UV light to provide a visually baseline for comparison, and visually confirmed that the polymer had no inherent fluorescence excitation. All samples also exhibited very good transparency, while an observed bluish color from the 0 wt % sample is an artifact of the bluish colors of the irradiated UV light, confirming a lack of fluorescence in the control sample.

FIG. 2 illustrates each of the images taken from a non-normally incident perspective view, allowing observation of dye emission that is not normally incident. While the omnidirectional fluorescence emission of the dye may suggest a loss of down-converted light, it's important to note that UV-A light cannot be efficiently contribute to the responsiveness of the solar cells, such as silicon (Si) solar cells. Namely, the efficiency of creating an electron-hole pair from UV-A photons is lower than that of photons with energies closer to the Si bandgap energy, resulting in a higher likelihood of energy dissipation as heat. Therefore, while a significant portion of the emitted photons may not reach the solar cell, any portion of the down-converted photon flux that is collected by the underlying solar cell can provide a nominal increase in energy conversion.

This increase is because the UV-A light would otherwise not be collected at all, owing to the lower efficiency of converting UV-A photons to electron-hole pairs in the Si solar cell.

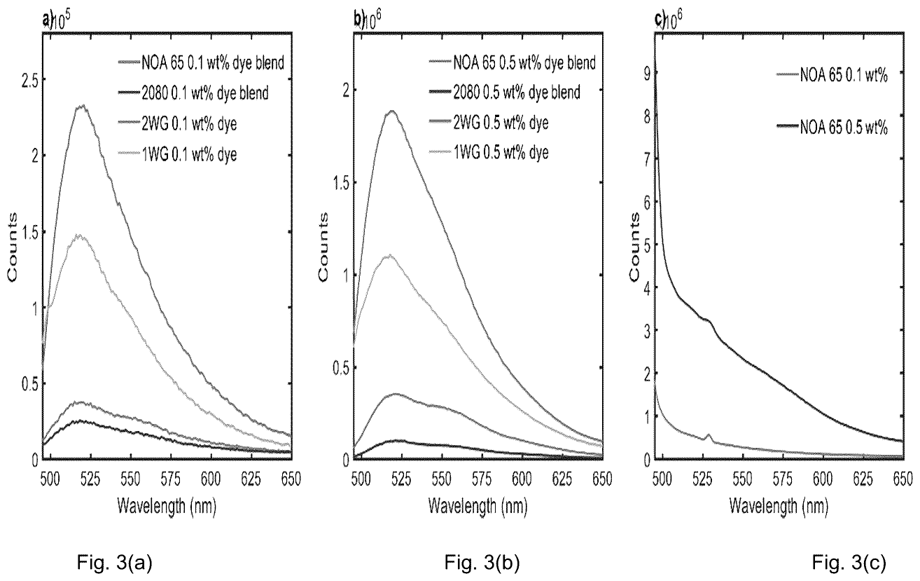

To delineate the effects of the different formulation components and structures, fluorescence spectra was collected from four (4) differently cured resins: i) a uniform resin made from only NOA65; ii) a uniform resin from the 20/80 polymer blend of NOA65 and the PDMS epoxide monomer; iii) a single (WG) waveguide structure produced from the blend; and iv) a double (2WG) waveguide structure produced from the blend. FIGS. 3(a)-3(c) presents fluorescence emission spectra from films made from each of above-noted resins. More specifically, the samples examined include photocurable resins (in liquid form) with NOA65 only and a binary mixture (20 wt % PDMS, 80 wt % NOA65), cured NOA65 resins, and single waveguide lattice (1WG) and multiwaveguide lattice (2WG) structures with either 0.1 or 0.5 wt % dye. FIG. 3(a) displays fluorescence emission spectra of all samples with 0.1 wt % dye, while FIG. 3(b) displays fluorescence emission spectra of samples with 0.5 wt % dye. FIG. 3(c) shows the fluorescence emission spectrum of cured NOA65 resin. For all samples shown in FIGS. 3(a) and 3(b), the dye was excited at 470 nm and the emission spectra were collected with a maximum intensity at ˜511 nm wavelength, with slight variation for all samples.

The fluorescence spectra obtained herein shows robust down-conversion and fluorescence of blue light excitation into the green to yellow region from all materials, regardless of the optical structure or dye concentration. The fluorescence emission increased with increased optical structure, that is, from a sample defined by a uniform structure, to samples having a single (WG) waveguide lattice structure, and finally to samples having a double (2WG) waveguide lattice structure. Additionally, the fluorescence emission increased by an order of magnitude when increasing the dye concentration from 0.1 to 0.5 wt %. Given that the fluorescent measurements were performed in transmission mode, this latter result may indicate the capability of waveguide lattice structures to confine and ensure light leaves the material at (closed to) normal incidence, which is an indicator of a beneficial property of controlling and re-directing light propagation, and that this effect is enhanced with the 2WG structure as compared to the WG structure. The waveguides collect the dye emission internally and coax light to propagate along their longitudinal axis towards the other side of the film toward the solar cell. This light direction is further enhanced considering that the waveguide cores are each composed of and rich with the fluorescent dye-tagged acrylate.

The herein described configuration ensures that the majority of the emission occurs inside the waveguide cores, thereby providing the highest likelihood of dye-emitted light being confined by the waveguides and transmitted along their lengths to the other side of the polymer film (the side to which the film is attached to the solar cell). In this sense, the inclusion of two waveguide lattices (the 2WG optical structure) increases the overall density of waveguides, on a per volume basis, and thus doubles the total excitation volume and the fraction of light that may be confined to and transmitted by a waveguide. Therefore, the fluorescence spectra in accordance with this embodiment provides evidence, at normal incidence, for the beneficial, synergistic, and multifunctional properties of polymer films that incorporate both light-active dye emission and the inclusion of single or double waveguide lattice structures. Increasing the dye content and the complexity of the lattice structure (via increasing the number of lattices) will both increase the overall dye-emitted flux.

Other observations can be considered from the fluorescent spectra, as presented according to FIGS. 3(a)-3(c). The concentration-dependent effect is expected, as the amount of dye available for excitation increases with increasing concentration. However, the emission intensity of 0.5 wt % for uniform films from NOA65 and a 20/80 mixture is reversed from those of uniform samples with 0.1 wt % dye, which could be owing to the quenching of excitation or scattering of emitted light. It should further be noted that fluorescence emission for the uniform samples increased from uncured to cured samples (data not shown), possibly due to greater degrees of cure providing better stability and less dissipation of excitation energy allowing for greater emission counts. This degree of cure may also play a role in the improved emission flux from the 2WG vs the 1WG structure, as the former has double the irradiation dosage (i.e., two LED sources employed), and thus can achieved both double the lattices in the polymer film, as well as overall greater degree of cure. Blends with polydimethylsiloxane (PDMS) show slightly lower intensity of fluorescence emission than the pure NOA65 films possibly due to energy transfer to PDMS upon excitation or loss of energy during emission to the chemical environment in the presence of PDMS.

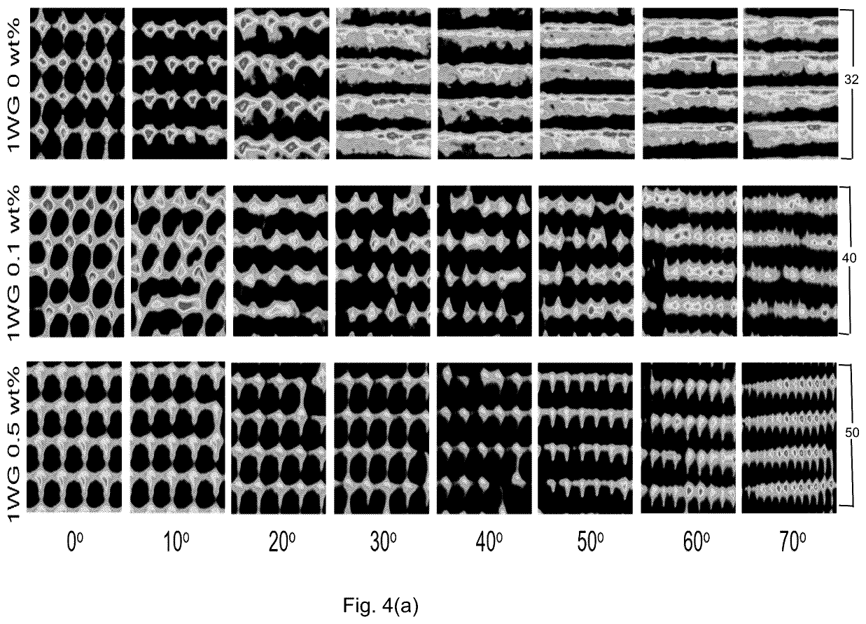

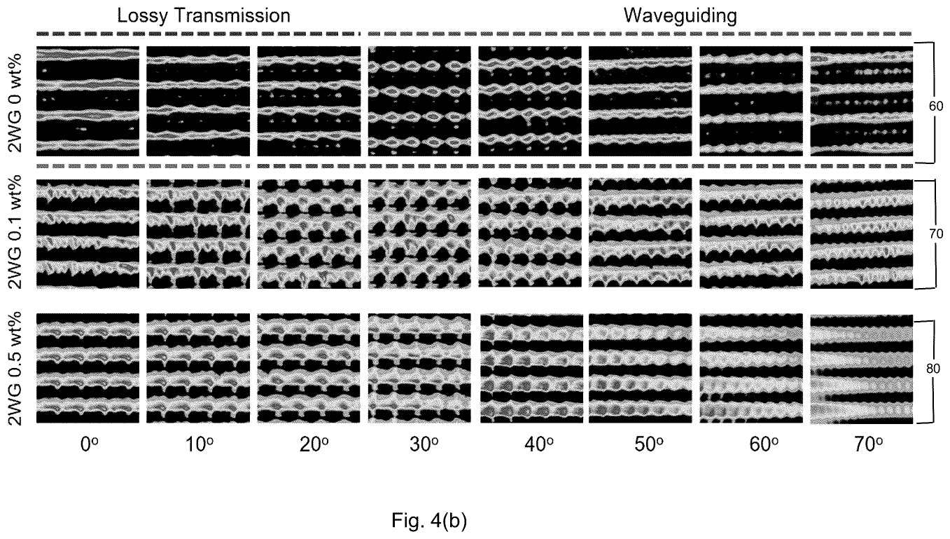

FIG. 4(a) depicts the transverse intensity profiles of transmitted incandescent light through a number of prepared vertically aligned single waveguide lattices (1WG) structures 32, 40, 50 having different dye concentrations (e.g., 0, 0.1, 0.5 wt %, respectively) as a function of incidence angle, shown on the horizontal axis between 0° and 70°. The spot intensities arranged in a periodic array are associated to confinement of light within the formed waveguide cores, indicating efficient collection and transmission of light through optical waveguiding. As evident from the profiles, 32, 40, 50, single WG structures with no dye 32 collect and transmit light through optical waveguiding within an angular range of 0 to 30°, as predicted by theoretical calculations based on refractive index differences. Importantly, incorporating dye into the waveguide lattice structure, 40, 50 extends the angular range of light confinement to the entire range examined, that is, from 0 to 70°. The spots in the optical intensity profile are smaller for waveguide lattices 50 produced with 0.5 wt % dye, indicating stronger confinement that may be associated with an increase in refractive index difference between the core and the cladding. This increase in refractive index difference indicated by the greater angular collection range can also explain the higher quality structures observed in the optical microscopy images of FIG. 1 and this greater contrast is associated to greater degrees of phase separation or the increase in refractive index associated to the incorporation of the dye in the formulation (and specifically in the waveguide cores).

For purposes of comparison, FIG. 4(b) displays the transverse intensity profiles of transmitted incandescent light through a number of 2WG optical structures 60, 70, 80 prepared with different dye concentrations (i.e., 0, 0.1, 0.5 wt %, respectively) and as a function of the incidence angle, shown on the horizontal axis between 0° and 70°. More specifically, those waveguide structures with no dye content 60 have an angular acceptance window between approximately 30 to 70 degrees, as observed previously. This particular range is delineated by the spotted nature of the transverse intensity profile, with the approximate circular shape of the intensity spots corresponding to the transmission of light from the waveguide cores. This result indicates that light is efficiently collected within the acceptance range of the waveguides at the entrance face of the film and is subsequently transmitted along the longitudinal axis of the waveguide cores to the other side of the film. Below this range, the intensity pattern appears smeared, as light can easily pass through the waveguide cores. 2WG structures, with each lattice oriented at slant angles with respect to the surface normal, can collect and transmit light at very wide angles. At low incidence angles, light that is beyond the acceptance range will pass through the waveguides, leading to a more smeared or lamellar pattern in the intensity profile. However, low angle incident light passing through the waveguides is not detrimental to the light collection process and can even be beneficial due to scattering interactions between the light and the waveguide lattices as shown for samples 70, 80.

The profiles presented in FIG. 4(b) further demonstrates that incorporating fluorescent dye into the 2WG structure results in the confinement of light to the waveguide cores across the entire angular range tested)(0-70°, as determined previously with the single WG structures, namely 32, 40, 50, and shown in FIG. 4(a). The periodicity of the spots resulting from the organized waveguide cores is evident, though distinct high intensity spots are less observable at lower incident angles. The incorporation of dye as in this described embodiment, therefore offers at least three (3) possible benefits: First, formulations with dye result in waveguides with higher refractive indices, enable a wider angular range of light to be collected due to the greater refractive index difference between the cores and the cladding. Second, light down-converted from the UV portion of the QTH lamp spectrum may be transmitted through the waveguides despite lossy transmission, thereby with sustainable total photon flux leaving the films. Third, since the dye is primarily in the waveguide cores, down-converted light emission also originates from the cores, wherein the resulting intensity profiles may reveal the expected differences in dye concentration between the waveguide cores and their surroundings. Overall, incorporating dye into the polymer structures enhances the angular acceptance range, providing superior omnidirectional capture of light from normal incidence to an ultra-wide angle of 70°.

Notably, larger spot sizes observed in dye-incorporated structures may result from the higher intensity flux of light transmitted through the waveguide cores. Additionally, the spotted nature of the transmitted intensity profiles 60, 70, 80, FIG. 4(b), across the angular range tested provides a visual confirmation of the refractive index profile, specifically the refractive index difference between the core and the cladding. This corroborates the enhanced refractive index difference and wide angular collection properties, which also indicates potentially higher degree of cure and phase separation between the core and cladding.

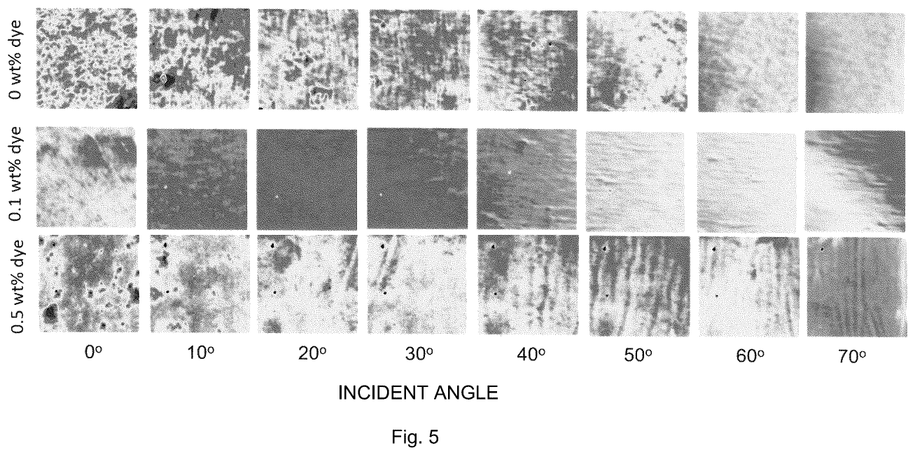

As shown in FIG. 5, NOA65 films produced with different dye concentrations show similar transverse intensity profiles, with a slight increase in intensity observed at mid-incident angles with 0.1 wt % dye The uniform intensity profile of the encapsulating provides confirmation of the uniformity of the photocuring process, indicating not significant spatial variations, which is important for subsequent synthesis of waveguide structures, in order to be assured that all waveguides in the lattice have similar structure composition. Some striations observed in the transmission from uniform samples at high incident angles may indicate some degree of convection during polymerization, but the uniformity of the waveguide lattices indicates that such variations do not affect the spatial consistency of the synthesized waveguide lattice structures.

Refractive index measurements did show that higher dye concentration yield a monotonic increase in the average index both in the pure NOA65 resins and the 20/80 PDMS/NOA65 polymer blends used to form the waveguide lattices, but only by a nominal amount of ˜0.003. This will translate into a slightly wider angular acceptance range of the waveguides, as would be determined by refractive index of high and low index components comprising of core-cladding architecture. The maximum acceptance range of waveguide arrays (without dye) is 30° based on the index of polymer (n_{NOA65}=1.627, n_{PDMS}=1.603). The refractive index difference in NOA65 between 0 wt % and 0.5 wt % dye is so small (Δn=0.0031), that the difference in angular acceptance range would not be discernible. Likewise, the light collection window of slanted waveguides with an angular orientation of 25° is determined first by the calculation of boundaries (θₐ) of collection range and rotating the boundaries by addition of waveguide angle, which gives the collection range of 25° up to 86°, and in the case of the structures produced here in with their slightly higher refractive index, the differences are boundaries would be 17-90°.

Hence, the incorporation of the fluorescent dye and the capability of these and other suitable light-sensitive formulations to have a higher refractive index can explain a portion of the extending of the collection window to a lower boundary from 25 degrees to approximately 17 degrees, though it does not completely explain light collection down to normal incidence (i.e., 0°). It is likely that the transmitted light observed below 17° is a combination of lossy transmission through the waveguides which, owing to the higher refractive index, is still able to preserve a greater fraction of light than otherwise possible without the dye or the contribution of light from dye emission. Regardless, the preservation of transmitted light flux through the polymer films, either through collection or dye emission, will ensure to greater flux of optical energy to the solar cell, as a means for sustained energy conversion as the incident angle of light varies. In other words, any loss in transmission of incident light may be compensated by dye excitation from the blue to UV-A and its consequent emission in the visible range.

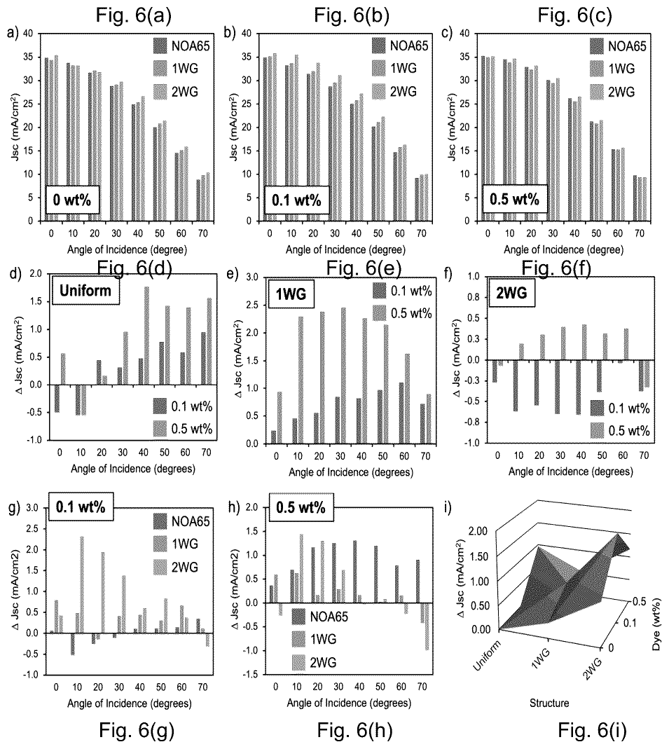

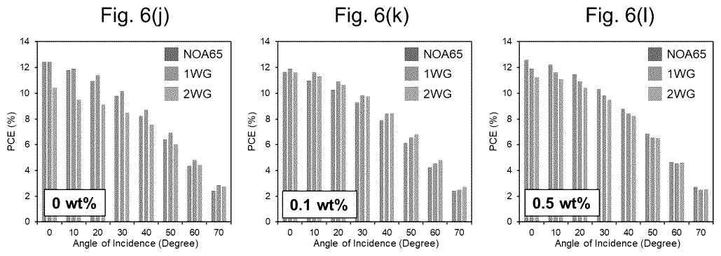

FIGS. 6(a)-6(f) provide a summary of current density measurements collected from solar tester experiments on each of the polymer films and dye concentrations prepared and examined; that is, samples prepared of pure NOA65 without optical (waveguide structures), samples prepared of a PDMS/NOA65 in a weight ratio of 20/80 to form WG and 2WG lattice structures, and with further inclusion of dye concentrations of 0, 0.1 wt % and 0.5 wt %. More specifically, FIGS.6(a)-6(c) illustrate short circuit current densities and FIGS. 6(d)-(f) represent nominal change (Δ/J_{SC}) for thin films with respect to the same structures with no dye. FIGS. 6(a)-6(c) represent thin films with 0, 0.1, and 0.5 wt % dye, respectively, for different structures. FIGS. 6(d)-6(f) represent uniform, WG, and 2WG structures, respectively, for different dye concentrations (control is each respective structure with no dye). FIGS. 6(g) and 6(h) represent 0.1 and 0.5 wt % dye concentrations, respectively, for different structures concentrations (control is corresponding structure with no dye). Finally, FIG. 6(i) shows a contour plot of the nominal change (Δ/J_{SC}) over all of the various optical structures and dye concentrations examined.

This collected data demonstrates the enhancement of solar cell current output with different dye concentrations and waveguide structures prepared in accordance with the present invention. As presented, the short circuit current densities (J_{SC}) are summarized by bar plots of their values for each angle of incidence examined. All current densities show a characteristic drop in value with increased angle of incidence associated to the shading effect of the front contacts and increase losses from Fresnel reflection at the air-polymer interface. Enhancement provided from either the dye and/or the waveguide structures are observed as nominal increases in Jsc relative to the control, either the uniform encapsulant, the films with no dye, or both.

In examining FIGS. 6(a-c), one key observation is that the use of a 2WG structure leads to higher total current output when compared to a single waveguide WG lattice or a uniform (no waveguide) encapsulant, especially at higher incident angles, over all dye concentrations. Another observation is that the addition of dye into the formulation consistently increases short circuit current density for incident angles in the range of 20 to 60°. However, the differences between dye and non-dye samples level out at 70°, possibly due to the extreme wide-angle nature of the incident light. With a dye concentration of 0.1%, a monotonic increase in current density over the entire angular incidence range is observed in the order of uniform, WG and 2WG structures. Examining the nominal average current densities (average over incident angle) relative of a uniform encapsulant with no dye, current density increases with increase in the number of lattices in the polymer film (i.e., 1WG, then 2WG). Also, a dye concentration of 0.1 wt % is optimal for both 1WG and 2WG structures. It is also evident that the 2WG structure with dye (0.1 and 0.5 wt %) provides the greatest enhancements in the nominal current density (1.87 and 1.17 mA/cm²), providing indication of the synergistic and beneficial nature of incorporating both dye composition and waveguide lattice structure in polymer encapsulant films for solar cells.

To gain more insight into the variations and dependencies of solar cell current density on dye concentration and waveguide structures, FIGS. 6(d)-(h) also provides plots of the nominal difference in short circuit current densities (ΔJ_{SC}) using two different controls: relative to a no-dye control while varying structure (FIGS. 6(d)-6(f)) and relative to a uniform control while varying dye (FIGS. 6(g)-6(h)), allowing for the clear observation and assessment of the enhancements in solar cell performance with respect to dye incorporation and structure. When structure was used as a control, uniform structures performed better with increasing dye concentration (0.5 wt %), particularly at the high angle range)(40-70° (FIG. 6(d)), while single (WG) structures provided enhancements over the entire angular range, which peak in the mid-angular range)(20-50° and increase with increasing dye concentration (FIG. 6(e)). 2WG structures with 0.5 wt % dye provided enhancement, whereas at 0.1 wt % only losses were observed (FIG. 6(f)). When dye concentration is fixed and structure is varied, we observed a current density increases for WG, and 2WG structures at 0.1 wt % dye (FIG. 6(g)), and current density increases for all structures at 0.5 wt %, with uniform encapsulants, providing the most consistent enhancement across the angular range, and WG and 2WG structures providing enhancements between 0-30° (FIG. 6(h)). At the highest dye concentration of 0.5 wt %, both uniform and 2WG structures performed relatively well, especially for the uniform structure over the entire angular range, and for the 2WG structure between 10-30°. This data is further demonstrated tabularly, as follows:

| | AM 1.5 G Solar Irradiation (dye content) (mA/cm²) | | | | | | | | |
|---|---|---|---|---|---|---|---|---|---|
| | NOA 65 | | | 2080, 1WG | | | 2080, 2WG | | |
| degree | 0% | 0.1% | 0.5% | 0% | 0.1% | 0.5% | 0% | 0.1% | 0.5% |
| 0° | 34.91 | 34.97 | 35.28 | 34.41 | 35.21 | 35.01 | 35.48 | 35.91 | 35.21 |
| 10° | 33.81 | 33.29 | 34.51 | 33.26 | 33.75 | 33.89 | 33.26 | 35.59 | 34.71 |
| 20° | 31.74 | 31.48 | 32.91 | 32.19 | 32.04 | 32.36 | 31.91 | 33.87 | 33.22 |
| 30° | 28.88 | 28.77 | 30.14 | 29.20 | 29.62 | 29.49 | 29.84 | 31.23 | 30.54 |
| 40° | 24.96 | 25.07 | 26.27 | 25.44 | 25.89 | 25.61 | 26.73 | 27.34 | 26.70 |
| 50° | 20.09 | 20.21 | 21.29 | 20.87 | 21.18 | 20.90 | 21.52 | 22.36 | 21.61 |
| 60° | 14.62 | 14.77 | 15.41 | 15.21 | 15.88 | 15.37 | 16.02 | 16.40 | 15.79 |
| 70° | 8.91 | 9.26 | 9.82 | 9.86 | 9.98 | 9.44 | 10.48 | 10.16 | 9.49 |

To gain further perspective on the effects of dye concentration and waveguide structure, the average current densities (averaged over all incident angles) were fitted to a linear regression model of current density=A*(structure)+B(dye concentration)+C, yield values of A=0.5, B=0.7, and C=0.08. Hence, the dye concentration and structure had a positive effect on current density, resulting in an average gain of 0.5 mA/cm² with the dye incorporation, while waveguide structure results in an average gain of 0.7 mA/cm². As these gains are averaged over the entire angular range, a positive gain in wide-angle light capture is also demonstrated, both through dye incorporation and the waveguide lattice.

By examining the iso-surface of gain in current density vs. both structure and dye concentration (FIG. 6(i)), maximal enhancements in the total nominal increase in current density was observed, particularly with two waveguide structures (2WG), which maximizes light collection via increased number of lattices in the polymer film, and with uniform structure with maximal dye concentration (0.5 wt %), which maximizes down-conversion. In other words, it is generally better to have either more lattices in the encapsulant or dye. A strong interaction is evidenced between dye concentration and waveguide structure, such that a lack of structure requires more dye to sustain a greater increase in current density, and likewise, less dye requires more optical (waveguide) structure in order to sustain a similar level of enhancement to the current density. Importantly, the positive slope along the diagonal from uniform with no dye to 2WG structures with 0.5 wt % dye shows a synergistic effect between the dye component and the waveguide structure, indicating that they interact with one another in a way that positively affects the current density. However, the saddle point between the two extremes of maximal dye and maximal waveguide structure indicates that a balance between waveguide structure and dye concentration that does not provide as much enhancement as the extremes (i.e., more dye and less lattices, or more lattices and less dye).

The trends observed in short-circuit current density with respect to waveguide structures are consistent with those on the quality of the structures. Specifically, the highest quality structure (1WG at 0.1 wt %) exhibits the highest current density compared to 1WG at 0 or 0.5 wt %. Additionally, improved quality in the 2WG structure, associated with increased dye concentration, corresponds to increased current density. These results highlight the mutual benefits of dye incorporation: the dye not only enhances the lattice structures' quality but also facilitates the confinement and transmission of the light it emits. The results also affirm structure-property-performance relationships discussed herein. As discussed herein, further enhancements may also be achieved by expanding the composition to include other light-active components, such as plasmonic nanoparticles on the bottom surface of the encapsulant (in contact with the solar cell), as well as anti-reflective coatings on the encapsulant surface.

With reference to FIGS. 6(j)-6(l), the power conversion efficiencies (PCEs) of the encapsulated solar cells were calculated over a range of dye concentrations (0 wt %, 0.1 wt % and 0.5 wt %, respectively) and waveguide structures, including WG and 2WG). Similarities and differences were observed and compared to the prior analysis applied to the short circuit current densities. In the case with no dye component (FIG. 6(j), single (WG) optical structures provided the highest efficiencies over the entire angular range. However, when considering short circuit current densities, there was a consistent advantage in increasing the number of waveguide structures (i.e., uniform, WG, and then 2WG). For a dye concentration of 0.1 wt % (FIG. 6(k), the WG structures provided maximal PCE, but at very wide incident angles, 2WG structures showed better efficiency. On the other hand, when examining the short circuit current densities, the 2WG waveguide structure was optimal over the entire angular range. With reference to FIG. 6(l) and at a dye concentration of 0.5 wt %, the uniform structure provided the best efficiencies. However, when considering the short circuit current densities, the performances were comparable. Overall, an analysis of the PCE values verifies that the combination of dye incorporation and waveguide structure can enhance solar cell performance. However, the incorporation of the dye has a stronger effect on the light conversion efficiency.

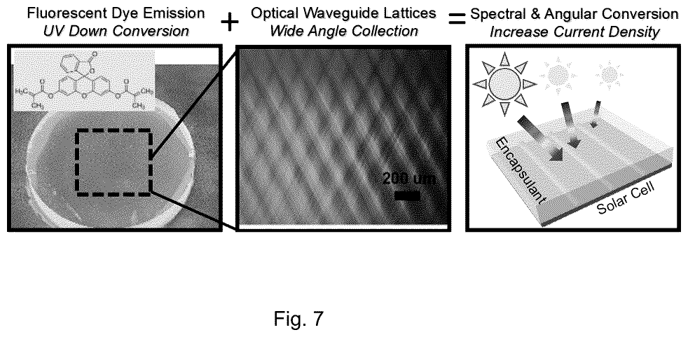

In this embodiment, the benefits of incorporating a fluorescent dye excited in the UV to blue region into polymer thin films used as encapsulants for silicon solar cells has been adequately and conclusively demonstrated. The inclusion of the fluorescent dye improved the quality of waveguide lattices produced, enabled down-conversion of blue to UV light into the visible regime, and increased the overall flux of light transmitted through the polymer films. These findings also revealed that the incorporation of the dye into the formulation enhanced the current output from solar cells and synergistically worked with waveguide lattices to provide greater transmission of light to the solar cell, leading to further enhancements in energy conversion and electrical output, as shown schematically according to FIG. 7.

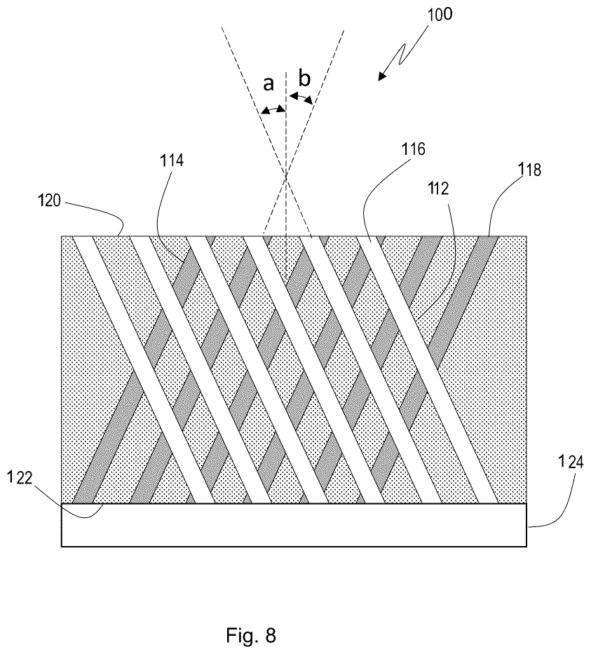

Other examples of exemplary composite polymer film made in accordance with aspects of the present invention are herein described. Referring to FIG. 8, a polymer composite film 10 in accordance with this embodiment is formed from the arrangement of four (4) components and has a preferred thickness of 2-3 mm. The composition of the polymer composite film 100 includes a high refractive acrylate monomer and silicone monomer, which are present in a 1:4 relative weight fraction in accordance with this specific embodiment similar to that previously described in the earlier embodiment, with a total fractional weight of 98%. Two (2) arrays of cylindrical waveguides 112 and 114 are provided to form a 2WG optical structure, with the waveguides of each array commonly forming a cylindrical core 116 made from the high refractive acrylate monomer and the low-refractive silicone monomer forming the cladding 118 surrounding each cylindrical core 116. According to this embodiment, the two arrays of waveguides 112 and 114 intersect one another as they extend from a first side 120 of the polymer composite film 120 facing the sun to an opposite second side 122 positioned onto a facing surface of a solar cell 124, shown partially in FIG. 8. According to this embodiment, the arrays of waveguides 112 and 114 each comprise 40 micron diameter cylindrical waveguides within a square array having a periodicity of 200 microns. The waveguide arrays 112 and 114 are disposed at an angle that is +/−30 degrees, relative to the material surface normal.

According to this specific embodiment, the polymer composite film 110 further comprises a fluorescent dye-tagged acrylate monomer, similar to that previously described in the earlier embodiment as well as the further inclusion of a quantity of nanoparticles. According to this specific embodiment, the nanoparticles are luminescent lanthanide doped yttrium oxide nanoparticles. The dye-tagged acrylate monomer is copolymerized with the acrylate monomer and located in the cylindrical cores 116, as well as in the cladding 118 of the cylindrical waveguides in the first and second arrays 112 and 114. The nanoparticles are dispersed in either or alternatively both of the cylindrical cores 116 and cladding 118 of each waveguide.

In accordance with this exemplary embodiment, the dye-tagged monomer comprises fluorescein O, O-dimethyacrylate, which as previously described in the first embodiment performs a down-conversion process relative to UV portions of the entering light. In a specific embodiment, the dye-tagged monomer is present at a weight fraction of 0.1 wt %, though this parameter can be suitably varied as in the prior described embodiment. The nanoparticles according to this exemplary embodiment are polyethylene glycol coated Erbium/Ytterbium doped yttrium oxide nanoparticles, each having a diameter of approximately 100 nm. The nanoparticles are present at a weight fraction of approximately 0.1 wt %. It will be understood that this parameter can also be suitably varied. The remaining weight of the composite film material includes a photoinitiator, such as camphorquinone (CQ), which is used to cure the composition and form the polymer composite film 100.

In use, the herein formed polymer composite film 100 is configured to downconvert ultraviolet (UV) light into visible light using the dye-tagged monomer. The film 100 is further configured to convert infrared (IR) light into visible light using the up-conversion nanoparticles. The herein described film 100 also has the capability to increase the current density specifically through the down-conversion of UV light by 1 mA/cm² and by virtue of the up-conversion of IR light by 1 mA/cm². The above down-conversion and up-conversion is tuned to emit light within the spectral response range of photovoltaic cells so that no changes are needed to the basic architecture or design of the solar cell. The multidirectional lattice created by the cylindrical waveguide arrays 112 and 114 also collects a wide range of incident light from −70 to +70 degrees according to this embodiment, and transmits the incident light into a more concentrated narrow angular range on the other side of the film 100 for receipt by the solar cell 124, which is positioned adjacently thereto. The multidirectional lattice of the cylindrical waveguide arrays 112 and 114 also directs down and upconverted light emitted from dye-tagged monomer and nanoparticles towards the solar cell 24, FIG. 8.

Solar cells that may be used in conjunction with the herein described polymer composite film 100 and variants thereof, including those previously described, include solar cells made from polycrystalline silicon, monocrystalline silicon, as well as organic solar cells, dye-sensitized solar cells, gallium arsenide, cadmium telluride, copper indium gallium selenide, and any other III-V semiconductors, and multijunction solar cells.

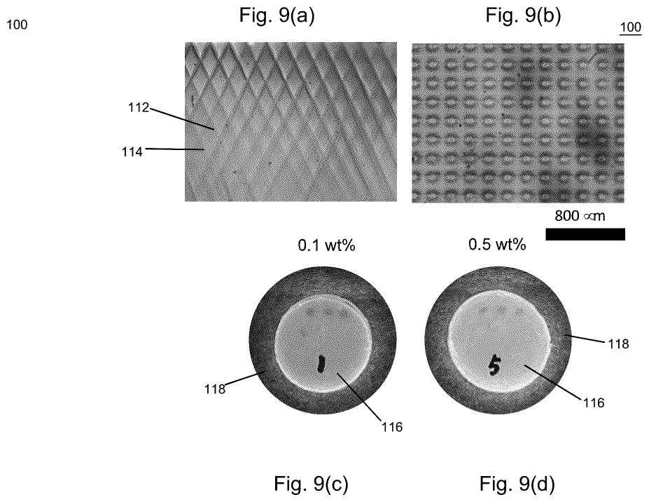

FIGS. 9(a) and 9(b) are optical microscopy images of the sample prepared according to that shown and described in FIG. 8, illustrating respective cross sectional and top surface views of the film and the waveguide arrays, 112, 114. FIGS. 9(c) and 9(d), illustrate images of fluorescence emission differences with the amount of dye concentration from 0.1 wt % (FIGS. 9(c) to 0.5 wt % (FIG. 9(d)) as evidenced by the increased brightness of the waveguide core 116.

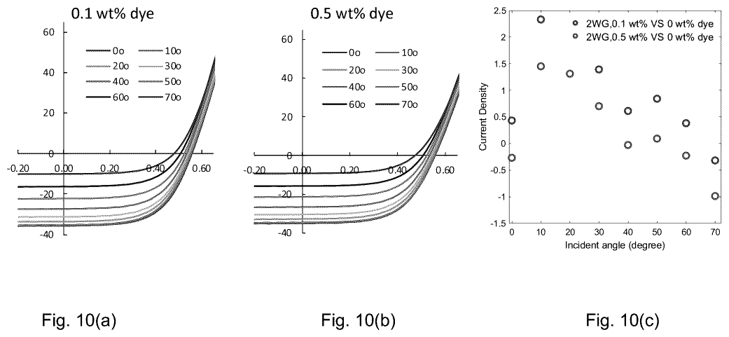

Discussion now relates to FIGS. 10(a)-12, in which FIGS. 10(a)-10(b) depict a series of J-V curves for an exemplary solar cell that has been encapsulated with a polymer composite film having various optical structures (waveguide lattices), with two different dye weight fractions; that is 0.1 wt % (FIGS. 10(a)) and 0.5 wt %; (FIG. 10(b)), while FIG. 10(c) illustrates a plot of the short circuit (V=0) current density as a function of light incident angle, with respect to a uniform polymer composite film having no dye content

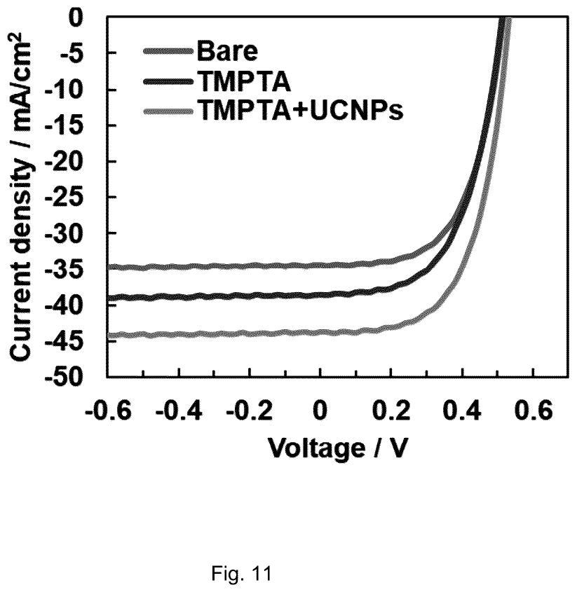

FIG. 11 presents a graph depicting various J-V curves for solar cells (polycrystalline Si) that have been encapsulated with structure at 0.1 wt % nanoparticles, demonstrating the enhancement in current density at short circuit (V=0) of the material with the up-conversion nanoparticles, as compared to a similar material with no nanoparticles, or even the bare solar cell,

With reference to the preceding figures, and when the film 100 is used in conjunction with a solar cell, the film can also increase the current density of the solar cell over the widened angular range from −70 to +70 degrees given the dispersion of the herein described optical structures. The film 100 also converts UV light (<300 nm) into visible light (400-700 nm), which may then be converted into photocurrent by the solar cell 24, FIG. 8, thus further increasing the current density. The film 100 further converts the IR light (>900 nm) into visible light (400-700 nm), which many then also be converted into photocurrent by the solar cell to even further the current density. The film 100 thus widens the effective spectral response of the solar cell by converting from the UV and IR portions of entering light into the useful range of the solar cell, thereby enabling the solar cell to subsequently convert the additional energy into electrical current.

The herein described polymer composite film 100 and suitable variants may be prepared by casting the synthesized film directly onto the surface of a bare solar cell, such as solar cell 24, FIG. 8. The film 100 can also be prepared as a free-standing solid film and then placed over the solar cell. More specifically and according to one embodiment, the four (4) components (high refractive index acrylate monomer, low refractive index silicon monomer, dye-tagged acrylate monomer and light conversion nanoparticles) may be mixed with a photoinitiator, such as camphorquinone (CQ) to prepare a photocurable resin, which may then be cast on a glass substrate or directly onto a solar cell. The acrylate monomer according to this embodiment is preferably Norland Optics resin (NOA 65). Other vinyl acrylate or methacrylate monomers with high refractive indices are also suitable, such as but not limited to Trimethylolpropane triacrylate (TMPTA). The silicone monomer may be an epoxide end-terminate dimethyle siloxane such as Gelest, DMS-09, although any epoxide terminate resin with a low refractive index is suitable. The photoinitiator may comprise camphorquinone (CQ) and (4-octyloxyphenyl) phenyliodonium hexafluoroantimonate (OPPI) in a 2:5 weight ratio. The photoinitiator according to this embodiment is ˜1-2 wt % of the total ratio.

The cured refractive index of the acrylate monomer must be higher than the cured refractive index of the silicone monomer or, more generally, the monomer used in the cladding 118, FIG. 8. The combined materials are prepared through radiation curing of the resin using either UV light emitted from a xenon lamp or blue light (˜470 nm) emitted from an LED light source. The irradiation intensity may be 4-12 mW/cm². Light from two separate light sources is transmitted through a photomask having 40 micron apertures in a square array of 200 micron spacing in order to generate the two arrays of optical structures. The light is passed through the resin, and the resin is allowed to cure, thereby creating the two arrays of cylindrical waveguides 112 and 114 at the desired angle relative to the material normal. The acrylate monomer cures to form the waveguide cores 116 and the silicone monomer phase separates into the surroundings so as to form the cladding 118, via photopolymerization-induced phase separation.

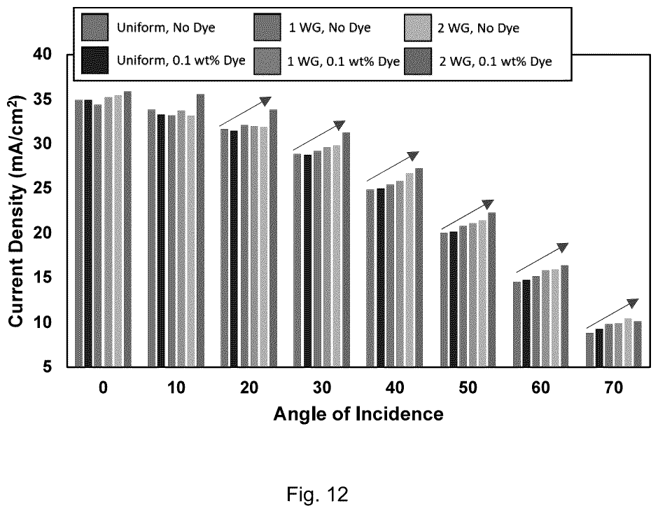

FIG. 12 is a graph summarizing angle-resolved solar tester requirements (AM 1.5 G) for polymer encapsulated solar cells having a dye concentration of (0.1 wt %)+optical waveguide (WG) structures. As seen in this figure, and especially at greater incident angles, a clear trend emerges in which the inclusion of either a dye or more waveguides, and more when both dye and waveguides are incorporated, in which Jse increases. The bar plot summarizes short-circuit (J_{SC}) current densities for illuminated solar cells with polymer structures: uniform with or without dye, a single vertically aligned WG lattice with or without dye, and two intersecting slant-angled)(±30°) waveguide lattices with or without dye. Hence, a comprehensive-structure-property performance relationship is evident. Improvements can be obtained with more in-depth studies of the structure, compositional distributions, as well as dependencies on the waveguide lattice parameters, such as waveguide diameter and lattice parameters.

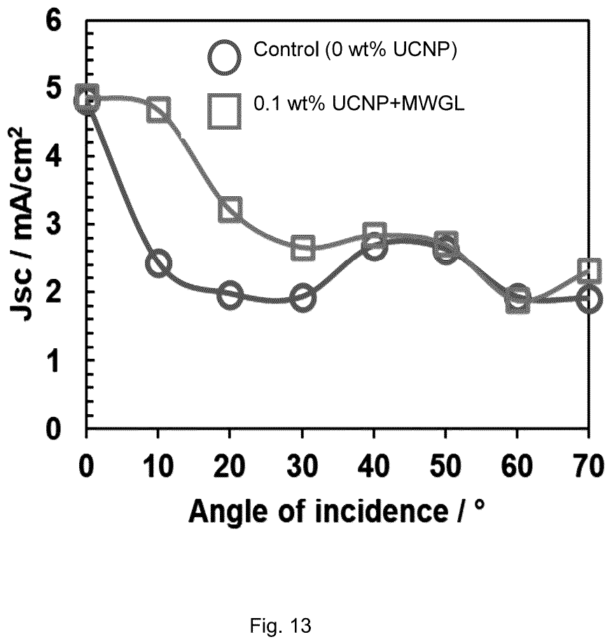

FIG. 13 is a graph of angle-resolved short circuit current density for solar cells, contrasting those encapsulated with a polymer composite film devoid of no up-conversion nanoparticles and a polymer composite film having a quantity of up-conversion nanoparticles (0.1 wt %) in which the solar cell is irradiated with broadband light >975 nm, to examine light conversion in the IR region. As can be gleaned from this latter figure, the differences in angle-resolved short circuit density for solar cells with either no up-conversion nanoparticles used as a control or with up-conversion nanoparticles (0.1 wt %) are evident. This figure clearly demonstrates the angle dependent conversion improvements which are realized by inclusion of the nanoparticles in accordance with this specific embodiment based on the combination of (optical) waveguide structures and light-responsive material (dye-tagged monomer and nanoparticles).

It will be understood that other dyes and nanoparticles may be used in order to specifically tune and shift the spectral response properties as well as tune the emission properties of the film in accordance with each of the herein described embodiments and variants. The distribution of the dye and nanoparticles can also be tuned through the synthesis conditions, such as, but not limited to the particular irradiation intensity. The dye-tagged monomer will be present in both the waveguide cores, as well as in the cladding with various distributions based on the synthesis conditions. The nanoparticle distribution can be suitably tuned to be within each of the waveguide cores, in the surrounding cladding, or a distribution of each, by tuning the irradiation intensity. The dye concentration can be varied from 0.1-1 wt % and the nanoparticle distribution can be varied from 0.1-1 wt %. Variations to the herein disclosed embodiment can further include changes to the dye tag monomer in order to suitably adjust the excitation and emission positions. Examples of alternative monomers for this purpose may include 9-Anthracenylmethyl methacrylate and 2-Naphthyl methacrylate. Variations can also include changes to the doping composition and dye to adjust the excitation and emission properties. Examples of acceptable dopants may include Erbium, Terbium, Hafnium, and their binary and ternary combinations.

While the invention has been described in terms of particular variations and illustrative figures, those of ordinary skill in the art will recognize that the invention is not limited to the variations or figures described. In addition, where methods and steps described above indicate certain events occurring in certain order, those of ordinary skill in the art will recognize that the ordering of certain steps may be modified and that such modifications are in accordance with the variations of the invention. Additionally, certain of the steps may be performed concurrently in a parallel process when possible, as well as performed sequentially as described above. Therefore, to the extent there are variations of the invention, which are within the spirit of the disclosure or equivalent to the inventions found in the claims, it is the intent that this patent will cover those variations as well.

To the extent that the claims recite the phrase “at least one of” in reference to a plurality of elements, this is intended to mean at least one or more of the listed elements, and is not limited to at least one of each element. For example, “at least one of an element A, element B, and element C,” is intended to indicate element A alone, or element B alone, or element C alone, or any combination thereof. “At least one of element A, element B, and element C” is not intended to be limited to at least one of an element A, at least one of an element B, and at least one of an element C.

This Detailed Description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form of contain, such as “contains” and “containing”) are open-ended linking verbs. As a result, a method or device that “comprises,” “has,” “includes,” or “contains” one or more steps or elements possesses those one or more steps or elements, but is not limited to possessing only those one or more steps or elements. Likewise, a step of a method or an element of a device that “comprises,” “has,” “includes,” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description set forth herein has been presented for purposes of illustration and description, but is not intended to be exhaustive or limited to the form disclosed. Many modifications and variations will be apparent to those of ordinary skill in the art without departing from the scope and spirit of the disclosure. The embodiment was chosen and described in order to best explain the principles of one or more aspects set forth herein and the practical application, and to enable others of ordinary skill in the art to understand one or more aspects as described herein for various embodiments with various modifications as are suited to the particular use contemplated and in accordance with the following appended claims. Additional embodiments include any one of the embodiments described above and described in any and all exhibits and other materials submitted herewith, where one or more of its components, functionalities or structures is interchanged with, replaced by or augmented by one or more of the components, functionalities or structures of a different embodiment described above.

### PARTS LIST FOR FIGS. 1-13

10 image
11 image
12 image
13 image
14 image
15 image
16 image
17 image
18 image
19 image
20 image
21 image
22 image
23 image
24 image
25 image
26 image
27 image
28 image
29 image
30 image
32 WG profiles, no dye
40 WG profiles, 0.1wt % dye
50 WG profiles, 0.5 wt % dye
60 2WG profiles, no dye
70 2WG profiles, 0.1wt % dye
80 2WG profiles, 0.5 wt % dye
100 film
112 first array of waveguides
114 second array of waveguides
116 cores, waveguide
118 cladding, waveguide
120 first side, film
122 second side, film
124 solar cell

It will be understood that there are other variations and modifications that will be readily apparent to a person of sufficient skill that are intended to be within the purview of the present invention as set forth herein and in accordance with the following appended claims.

1. An encapsulant for a solar cell, comprising:
a film having a first side and an opposing second side;
at least one optical structure formed in the film, the at least one optical structure comprising at least a first waveguide array positioned between the first and second sides, wherein each waveguide in the at least one first waveguide array is commonly oriented at a first angle relative to a normal of a surface of the film and in which each waveguide of the first waveguide array is formed by a core of a high-refractive index polymer and a cladding of a low refractive index polymer; and
at least one light conversion material disposed in the core of each waveguide, in which the at least one light conversion material comprises an organic or inorganic fluorescent dye is capable of downconverting UV portions of light entering the film into visible light.

2. The encapsulant according to claim 1, wherein the high-refractive index polymer is an acrylate, the low refractive-index polymer is a silicone and the at least one light conversion material is a fluorescent dye-tagged acrylate.

3. The encapsulant according to claim 1, wherein the at least one optical structure further comprises a second waveguide array formed in the film and positioned between the first and second sides, the second waveguide array having a plurality of waveguides commonly oriented at a second angle relative to the normal of a surface of the film.

4. The encapsulant according to claim 3, wherein the first angle and the second angle of the first and second waveguide arrays are equal and opposite to one another.

5. The encapsulant according to claim 1, wherein the at least one light conversion material further comprises a quantity of nanoparticles dispersed in the film, the nanoparticles being capable of up-converting IR portions of light entering the first side into visible light.

6. The encapsulant according to claim 2, in which the high refractive index acrylate and the low refractive index silicone are present in a weight ratio of 1:4, respectively.

7. The encapsulant according to claim 5, in which the nanoparticles are lanthanide doped yttrium oxide nanoparticles.

8. The encapsulant according to claim 4, wherein the first and second angles are in the range of −30 to about 30 degrees.

9. The encapsulant according to claim 5, in which the nanoparticles are dispersed in at least the waveguide cores or the waveguide cores and the cladding of the film.

10. An encapsulant for a solar cell, comprising:
a film having a first side and an opposing second side;
a first waveguide array formed in the film and positioned between the first and second sides, wherein each waveguide in the first waveguide array is commonly oriented at a first angle relative to a normal of a surface of the film;
a second waveguide array formed in the film and positioned between the first and second sides, wherein each waveguide in the second waveguide array is commonly oriented at a second angle relative to a normal of a surface of the film;
wherein each waveguide of the first waveguide array and each waveguide of the second waveguide array is formed by a core of a high-refractive index polymer and a cladding of a low refractive index polymer;
wherein the first angle and second angle are opposite to one another relative to a normal of the surface of the film; and
at least one light conversion material included in the formed core or cladding of each waveguide of the first and second waveguide array.

11. The encapsulant according to claim 10, wherein the at least one light conversion material further comprises a quantity of nanoparticles dispersed in the film, the nanoparticles being capable of up-converting IR portions of light entering the first side into visible light.

12. The encapsulant according to claim 10, in which the high refractive index polymer is an acrylate and the low refractive index polymer is a silicone, in which the acrylate and silicone are present in a weight ratio of 1:4, respectively.

13. The encapsulant according to claim 11, in which the quantity of nanoparticles are lanthanide doped yttrium oxide nanoparticles.

14. The encapsulant according to claim 10, in which the at least one light conversion material is a fluorescent dye-tagged acrylate capable of down-converting UV portions of light entering the first side of the film via the at least first and second waveguide arrays into visible light.

15. The encapsulant according to claim 10, wherein the first and second angles are in the range of −30 degrees to about 30 degrees.

16. The encapsulant according to claim 11, in which the quantity of nanoparticles are dispersed in at least one of the waveguide cores and the waveguide cores and the cladding of the film.

17. An encapsulant for a solar cell, comprising:
a film having a first side and an opposing second side;
a first waveguide array formed in the film and positioned between the first and second sides, wherein each waveguide in the first waveguide array is commonly oriented at a first angle relative to a normal of a surface of the film;
a second waveguide array formed in the film and positioned between the first and second sides, wherein each waveguide in the second waveguide array is commonly oriented at a second angle relative to a normal of a surface of the film;
wherein each waveguide of the first waveguide array and each waveguide of the second waveguide array is formed by a core of a high-refractive index acrylate monomer and a cladding of a low refractive index epoxide monomer;
wherein the first angle and second angle are opposite to one another relative to a normal of the surface of the film; and
a light converting material comprising a quantity of nanoparticles disposed in the first and second waveguide arrays, the nanoparticles being capable of upconverting IR portions of light entering the first side into visible light.

18. The encapsulant according to claim 17, wherein the light converting material further comprises a fluorescent dye-tagged acrylate included in the formed core of each waveguide of the first and second array of waveguides and capable of downconverting UV portions of light entering the first side into visible light.

19. The encapsulant according to claim 17, wherein the quantity of nanoparticles are lanthanide doped yttrium oxide nanoparticles.

20. The encapsulant according to claim 17, wherein the nanoparticles are dispersed in at least the waveguide cores or the waveguide cores and the cladding of the waveguide arrays.
